(19) United States
(12) Patent Application Publication
(10) Pub. No.: US 2025/0083331 A1
(43) Pub. Date: Mar. 13, 2025

(54) SUBSTRATE HOLDING HAND AND SUBSTRATE CONVEYOR ROBOT

(71) Applicant: KAWASAKI JUKOGYO KABUSHIKI KAISHA, Kobe-shi, Hyogo (JP)

(72) Inventor: Shinya KINOSHITA, Kobe-shi (JP)

(73) Assignee: KAWASAKI JUKOGYO KABUSHIKI KAISHA, Kobe-shi, Hyogo (JP)

(21) Appl. No.: 18/729,801

(22) PCT Filed: Dec. 21, 2022
(86) PCT No.: PCT/JP2022/047170

§ 371 Date: Jul. 17, 2024

(30) Foreign Application Priority Data
Jan. 25, 2022 (JP) 2022-009265

(51) Int. Cl. B25J 11/00; B25J 15/00; H01L 21/687

(52) U.S. Cl. CPC B25J 11/0095; B25J 15/0014; H01L 21/68707

(57) ABSTRACT

A substrate-holding hand includes a plurality of blades for supporting substrates and stacked with the plurality of blades being spaced away from each other; and a support mechanism for supporting the plurality of blades. Each of the plurality of blades is connected to the support mechanism by an eccentric element.

### TECHNICAL FIELD

The present disclosure relates to a substrate-holding hand and a substrate-conveying robot.

### BACKGROUND ART

Substrate-conveying robots including a substrate-holding hand are known in the art. Japanese Patent Laid-Open Publication No. JP2006-313865 discloses a substrate-holding apparatus including a plurality of blades for holding substrates, and a pitch-changing mechanism for changing a pitch between the blades. The pitch-changing mechanism in Japanese Patent Laid-Open Publication No. JP2006-313865 includes blade attachment plates attached to base ends of the plurality of blades. The blade attachment plates are attached to a pitch conversion cylinder. The pitch conversion cylinder moves the blade attachment plates frontward and backward to change the pitch between the blades.

### PRIOR ART

### Patent Document

Patent Document 1: Japanese Patent Laid-Open Publication No. JP2006-313865

### SUMMARY OF THE INVENTION

In the substrate-holding apparatus in Japanese Patent Laid-Open Publication No. JP2006-313865, the pitch between the plurality of blades is changed by moving the blade attachment plates upward and downward by using the pitch conversion cylinder. However, the pitch between the blades is not set at a desired pitch due to deviation of attachment of the blade attachment plates in some cases. In such a case, a work activity for fine adjustment of the pitch between the blades for supporting the substrates takes time and effort. To address this, it is desired to easily perform fine adjustment of the pitch between the blades for supporting the substrates.

The present invention is intended to solve the above problem, and to provide a substrate-holding hand and a substrate-conveying robot capable of easily performing fine adjustment of a pitch between blades.

A substrate-holding hand according to a first aspect of the present disclosure includes a plurality of blades for supporting substrates and stacked with the plurality of blades being spaced away from each other; and a support mechanism for supporting the plurality of blades, wherein each of the plurality of blades is connected to the support mechanism by an eccentric element.

In the substrate-holding hand according to the first aspect of the present disclosure, as discussed above, each of the plurality of blades is connected to the support mechanism by the eccentric element. According to this configuration, because a height position of an upper end part of the eccentric element is changed by changing a rotation angle of the eccentric element, it is possible to correspondingly change a height position of the blade relative to the support mechanism. Consequently, fine adjustment of the pitch between the blades can be easily performed simply by changing the rotation angle of the eccentric element, which connects each of the plurality of blades to the support mechanism.

A substrate-conveying robot according to a second aspect of the present disclosure includes a robot arm; and a substrate-holding hand arranged in a distal end part of the robot arm, wherein the substrate-holding hand includes a plurality of blades for supporting substrates and stacked with the plurality of blades being spaced away from each other, and a support mechanism for supporting the plurality of blades, and each of the plurality of blades is connected to the support mechanism by an eccentric element.

In the substrate-conveying robot according to the second aspect of the present disclosure, as discussed above, each of the plurality of blades is connected to the support mechanism by the eccentric element. According to this configuration, because a height position of an upper end part of the eccentric element is changed by changing a rotation angle of the eccentric element, it is possible to correspondingly change a height position of the blade relative to the support mechanism. Consequently, it is possible to provide a substrate-conveying robot capable of easily performing fine adjustment of the pitch between the blades simply by changing the rotation angle of the eccentric element, which connects each of the plurality of blades to the support mechanism.

It is possible to easily perform fine adjustment of the pitch between the blades.

### BRIEF DESCRIPTION OF THE DRAWINGS

FIG. 1 is a diagram showing a configuration of a substrate-conveying robot according to a first embodiment.

FIG. 2 is a perspective view showing a linkage with a pitch between blades being large.

FIG. 3 is a view showing the linkage with the pitch between the blades being large as viewed in a Y1 side.

FIG. 4 is a view showing the linkage with the pitch between the blades being small as viewed in the Y1 side.

FIG. 5 is a view showing a connection part of the blade.

FIG. 6 is a view showing the connection part of the blade and an eccentric element.

FIG. 7 is a view showing the blade whose height position is adjusted upward by fine adjustment.

FIG. 8 is a view showing the blade whose height position is adjusted downward by fine adjustment.

FIG. 9 is a view showing connection between the connection part of the blade and a second link.

FIG. 10 is a view showing biasers according to a second embodiment.

FIG. 11 is a view showing a weight according to a first modified embodiment.

FIG. 12 is a view showing a weight according to a second modified embodiment.

### MODES FOR CARRYING OUT THE INVENTION

Embodiments embodying the present disclosure will be described with reference to the drawings.

### First Embodiment

### (Configuration of Substrate-Conveying Robot)

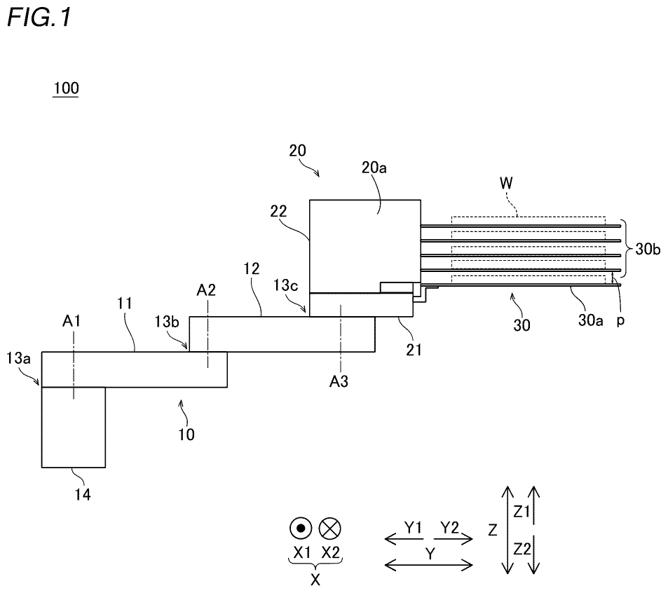

The following description describes a configuration of a substrate-conveying robot 100 according to a first embodiment with reference to FIGS. 1 to 9. As shown in FIG. 1, the substrate-conveying robot 100 includes a robot arm 10, and a substrate-holding hand 20.

In this specification, the upward/downward direction is defined as a Z direction. An upper side is defined a Z1 side, and a lower side is defined as a Z2 side. A direction orthogonal to the Z direction is defined as an X direction. One side in the X direction is defined as an X1 side, and another side is defined as an X2 side. A direction orthogonal to the Z direction and the X direction is defined as a Y direction. One side in the Y direction is defined as an Y1 side, and another side is defined as an Y2 side.

The robot arm 10 is a horizontal multi-joint robot arm. The robot arm 10 includes a first arm 11 and a second arm 12. One end of the first arm 11 is connected to a base 14 through a first joint 13a. One end of the second arm 12 is connected to another end of the first arm 11 through a second joint 13b. The substrate-holding hand 20 is connected to another end of the second arm 12 through a third joint 13c. Drive mechanisms including servo motors, which are rotational driving sources, rotational position sensors for detecting rotational positions of output shafts of the servo motors, and power transmission mechanisms that transmit outputs of the servo motors to the joints are arranged in the joints of the first joint 13a, the second joint 13b and the third joint 13c. The first joint 13a, the second joint 13b and the third joint 13c rotate about a first rotation axis A1, a second rotation axis A2, and a third rotation axis A3, respectively, extending in a vertical direction.

### (Configuration of Substrate-Holding Hand)

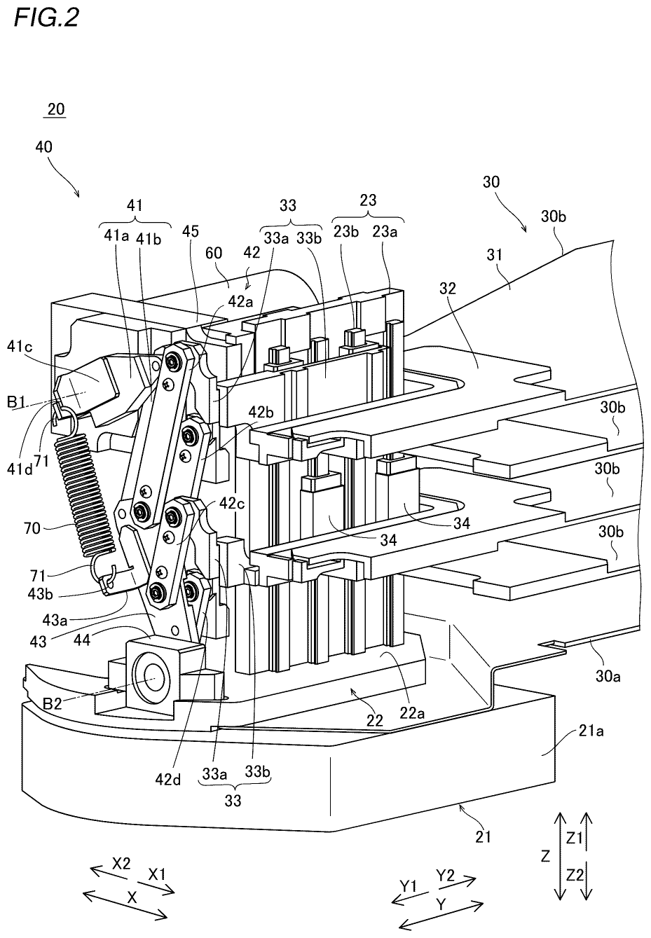

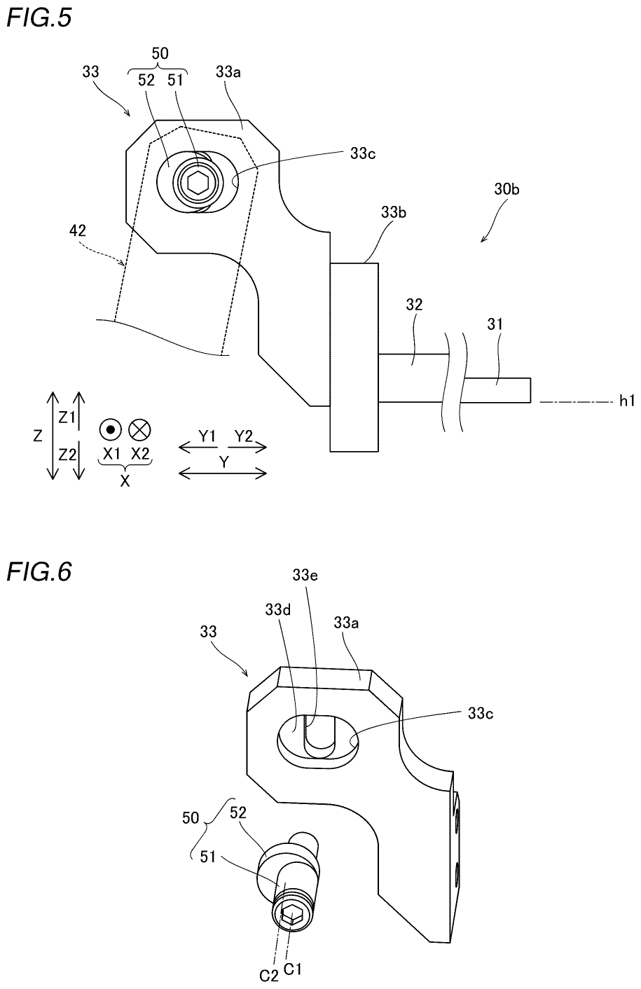

As shown in FIG. 2, the substrate-holding hand 20 includes blades 30, a linkage 40 eccentric bolts 50 shown in FIG. 6, a driver 60 and a biaser 70. In FIGS. 2, 3 and 4, a cover 20a shown in FIG. 1, which covers the linkage 40, the eccentric bolts 50, the driver 60 and the biaser 70, is omitted. The linkage 40 is an example of a support mechanism. The eccentric bolt 50 is an example of an eccentric element.

The substrate-holding hand 20 is arranged in a distal end part of the robot arm 10, as shown in FIG. 1. As described above, the substrate-holding hand 20 is connected to another end of the second arm 12.

As shown in FIG. 1, the substrate-holding hand 20 includes a first substrate-holding hand 21 and a second substrate-holding hand 22. The second substrate-holding hand 22 is arranged above the first substrate-holding hand 21, and operates independently of the first substrate-holding hand 21. Specifically, the first substrate-holding hand 21 is connected to another end of the second arm 12. The second substrate-holding hand 22 is connected to the first substrate-holding hand 21. The second substrate-holding hand 22 is rotated about the third rotation axis A3.

In the first embodiment, a plurality of blades are provided as the blades 30 as shown in FIG. 1. The plurality of blades 30 for supporting substrates W are stacked with the plurality of blades being spaced away from each other. Each of a plurality of blades 30 include a blade body 31, a support 32 and a connection part 33 as shown in FIG. 2. The blade body 31 supports the substrate W. The blade body 31 has a Y shape having two forked ends. The blade body 31 has a thin plate shape. The shape of the blade body 31 is not limited to the Y-shape and the thin-plate shape. The support 32 supports the blade body 31. The support 32 is arranged in a proximal end part of the blade body 31. The connection part 33 connects the support 32 to a second link 42, which will be described later. The connection part 33 includes a first connection part 33a connected to the second link 42, and a second connection part 33b connecting the first connection part 33a to the support 32. That is, the blade body 31, the support 32, the second connection part 33b, the first connection part 33a, and the second link 42 are connected in this order to each other.

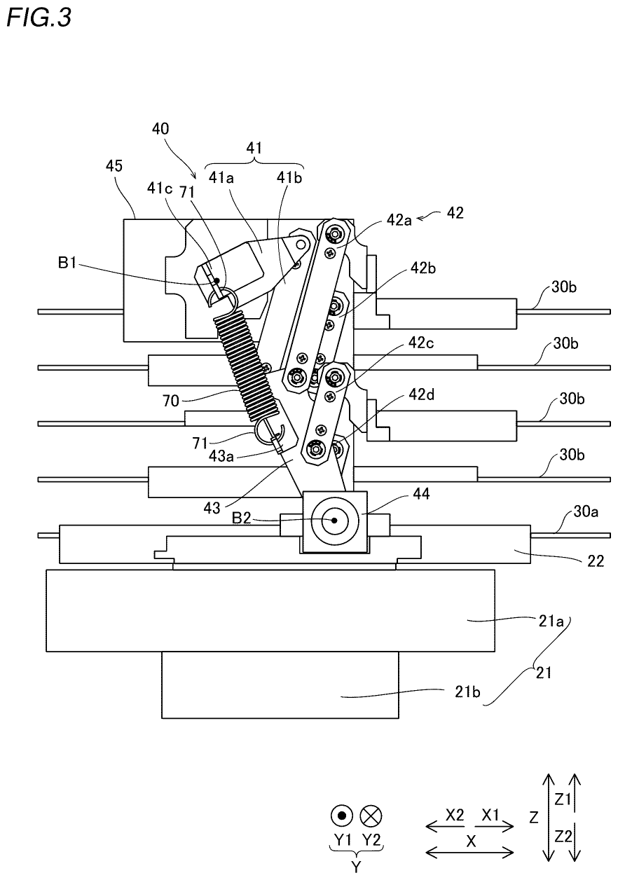

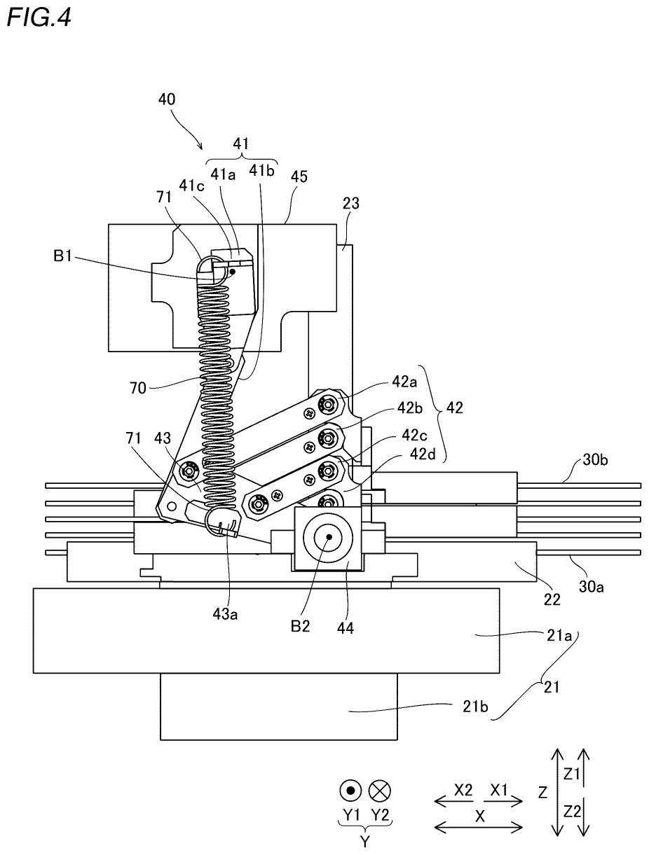

In the first embodiment, the blades 30 includes a first blade 30a and second blades 30b as shown in FIG. 1. The first blade 30a is provided to the first substrate-holding hand 21. The first blade 30a is fixed to the first substrate-holding hand 21. One blade is provided as the first blade 30a. The second blades 30b are provided to the second substrate-holding hand 22. In the second blades 30b, as shown in FIGS. 3 and 4, a pitch p between the second blades 30b is changed by the linkage 40. Four blades are provided as the second blades 30b, for example. The configurations of the plurality of second blades 30b are similar to each other. The pitch p between the second blades 30b refers to a gap between the second blades 30b adjacent to each other in the Z direction.

As shown in FIG. 3, the first substrate-holding hand 21 includes a base part 21a and a connection part 21b. The first blade 30a is attached to the base part 21a. The connection part 21b is connected to the second arm 12.

As shown in FIG. 2, the second substrate-holding hand 22 includes a base part 22a, a guide 23 and the linkage 40. The base part 22a is connected to the base part 21a of the first substrate-holding hand 21. The guide 23 is attached to the base part 22a. The guide 23 guides movements of the second blades 30b in the Z direction when the pitch p between the second blades 30b is changed by the linkage 40. Specifically, the guide 23 includes a support stand 23a and guide rails 23b. The support stand 23a has a plate shape extending in the Z direction. A plurality of guide rails are provided as the guide rails 23b having a rod shape extending in the Z direction. Specifically, four guide rails 23b are arranged on each of both sides, which are the X1 and X2 sides, of the support stand 23a.

The second connection part 33b of the second blade 30b that is positioned at a first level from a top side is guided by the guide rails 23b. The second connection part 33b of the second blade 30b that is positioned at a second level from the top side is similarly guided by the guide rails 23b. The second blade 30b that is positioned at a third level from the top side includes guided parts 34 to be guided by the guide rails 23b. The second blade 30b that is positioned at a fourth level from the top side also includes guided parts 34 to be guided by the guide rails 23b.

In the first embodiment, the linkage 40 supports the plurality of blades 30, and changes the pitch p between blades 30. Specifically, the linkage 40 supports the second blades 30b, and changes the pitch p between the second blades 30b. A pitch p between the second blades 30b that is positioned at the bottom level and the first blade 30a is correspondingly changed by changing the pitch p between the second blades 30b by the linkage 40. The linkage 40 converts rotation of the driver 60 into movement of the blades 30 in the Z direction.

In the first embodiment, the linkage 40 includes a first link 41, second links 42, and a third link 43. The first link 41 is connected to the driver 60. Each of a plurality of second links as the second links 42 is connected to corresponding one of the blades 30, and the third links 43 connect the plurality of second links 42 to each other. The first link 41, the second links 42, and the third link 43 are formed of a metal, and have plate shapes. The first link 41, the second link 42 and the third link 43 may be formed of materials other than metals, and may have shapes other than plate shapes. The first link 41, the second link 42, and the third link 43 are examples of links.

Specifically, the first link 41 includes a first part 41a and a second part 41b. One end of the first part 41a is connected to a driving shaft of the driver 60. The first part 41a is rotated by a driving force of the driver 60. One end of the first part 41a is rotated about an axis B1 extending in the Y direction. Another end of the first part 41a is connected to one end of the second part 41b. Another end of the second part 41b is connected to one end of the third link 43. Also, the first link 41 and the driver 60 are supported by a support 45 connected to the support stand 23a of the guide 23.

One end of each second link 42 is connected to the third link 43. Another end of each second link 42 is connected to corresponding one of the second blades 30b. Four second links as the second links 42 are correspondingly provided to the four second blades 30b. A second link 42a and a second link 42c, which are connected the first second blade 30b and the third second blade 30b, respectively, from the top side in the four second blades 30b, are connected to the Y1 side of the third link 43. A second link 42b and a second link 42d, which are connected the second second blade 30b and the fourth second blade 30b, respectively, from the top side, are connected to the Y2 side of the third link 43. A relationship between lengths of the second link 42a, the second link 42b, the second link 42c and the second link 42d is represented by the length of the second link 42a>the length of the second link 42b>the length of the second link 42c>the length of the second link 42d. The second link 42a, the second link 42b, the second link 42c and the second link 42d are examples of links.

One end of the third link 43 is connected to another end of the second part 41b of the first link 41. Another end of the third link 43 is connected to the support 44 arranged on the base part 22a. Another end of the third link 43 is rotated about an axis B2 extending in the Y direction.

The driver 60 drives the linkage 40. As described above, the driver 60 is connected to the first part 41a of the first link 41, and rotates the one end of the first part 41a about the axis B1. The driver 60 is an actuator that rotates the first link 41. For example, the driver 60 is a servo motor.

### (Biaser)

In the first embodiment, the biaser 70 is provided separately from the driver 60, which drives the linkage 40. The biaser 70 applies a force to the linkage 40 in a direction that increases the pitch p between the blades 30. The biaser 70 biases the linkage 40 in the direction that increases the pitch p between the blades 30.

In the first embodiment, the biaser 70 is connected to the first link 41 and the third link 43. The biaser 70 includes a pulling coil spring that applies a pulling force to the first link 41 to rotate the first link in the direction that increases the pitch p between the blades 30. Specifically, the biaser 70 includes circular hooks 71 on its both ends. The first link 41 includes a biaser attachment part 41c. The third link 43 includes a biaser attachment part 43a. The biaser attachment part 41c and the biaser attachment part 43a have L shapes, and protrude toward the Y1 side. The biaser attachment part 41c and the biaser attachment part 43a have a notch 41d and a hole 43b, respectively. The hooks 71 on the both ends of the biaser 70 are attached to the notch 41d of the biaser attachment part 41c and the hole 43b of the biaser attachment part 43a. Only one biaser is provided as the biaser 70.

In the first embodiment, the pitch p between the second blades 30b is changed by the driver 60 with a biasing force being applied against own weights of the second blades 30b by the biaser 70. Also, balance is achieved between the force that is applied by the biaser 70 and the own weights of the plurality of second blades 30b without a driving force of the driver 60. If the plurality of second blades 30b are not attached to the substrate-holding hand 20, an angle formed between the first part 41a and the third link 43 of the linkage 40 is maximized by the biasing force of the biaser 70. When the plurality of second blades 30b are attached to the substrate-holding hand 20, the angle formed between the first part 41a and the third link 43 of the linkage 40 is reduced by a certain amount of degrees. Accordingly, balance is achieved between the force that is applied by the biaser 70 and the own weights of the plurality of second blades 30b. As a result, operators can move the second blades 30b in the Z direction with a relatively small force under a condition in which the driving force of the driver 60 is not applied.

Also, the pitch p between the second blades 30b is changed by the driver 60 with balance being achieved between the biasing force of the biaser 70 and the own weights of the plurality of second blades 30b. As shown in FIG. 3, the pitch p between the second blades 30b is large under a condition in which balance is achieved between the biasing force of the biaser 70 and the own weights of the plurality of second blades 30b. As shown in FIG. 4, the pitch p between the second blades 30b is reduced by rotating the first part 41a of the first link 41 counterclockwise by using the driver 60. Because a rotation amount of the driver 60 can be continuously varied, the pitch p between the second blades 30b can be continuously varied.

### (Eccentric Element)

In the first embodiment, eccentric bolts 50 connect the plurality of blades 30 to the linkage 40, as shown in FIG. 5. As shown in FIG. 6, the eccentric bolt 50 includes a shaft 51, and a disk-shaped flange 52 eccentrically arranged from a rotation center axis C1 of the shaft 51. The eccentric bolt 50 is an element that has the rotation center axis C1 of the shaft 51 and a rotation center axis C2 of the disk-shaped flange 52 offset from the rotation center axis C1. The eccentric bolt 50 serves as an element for fine adjustment of the height position of the blade 30 in the Z direction.

In the first embodiment, each of the plurality of second blades 30b is connected to corresponding one of the plurality of second links 42 by corresponding one of the eccentric bolts 50. The second blade 30b has a hole 33c. The hole 33c is arranged in the first connection part 33a of the connection part 33. The eccentric bolt 50 includes a shaft 51, and a flange 52 eccentrically arranged from a rotation center axis C1 of the shaft 51. The eccentric bolt 50 is inserted into the hole 33c. The second blade 30b is moved upward and downward by rotating the eccentric bolt 50 inserted in the hole 33c with the flange 52 being in contact with an interior side surface of the hole 33c. This arrangement allows fine adjustment of the height position of the second blade 30b. In addition, a bottom part 33d is arranged in the hole 33c. A hole 33e is arranged in the bottom part 33d. The flange 52 is in contact with the bottom part 33d with the eccentric bolt 50 being inserted into the hole 33e.

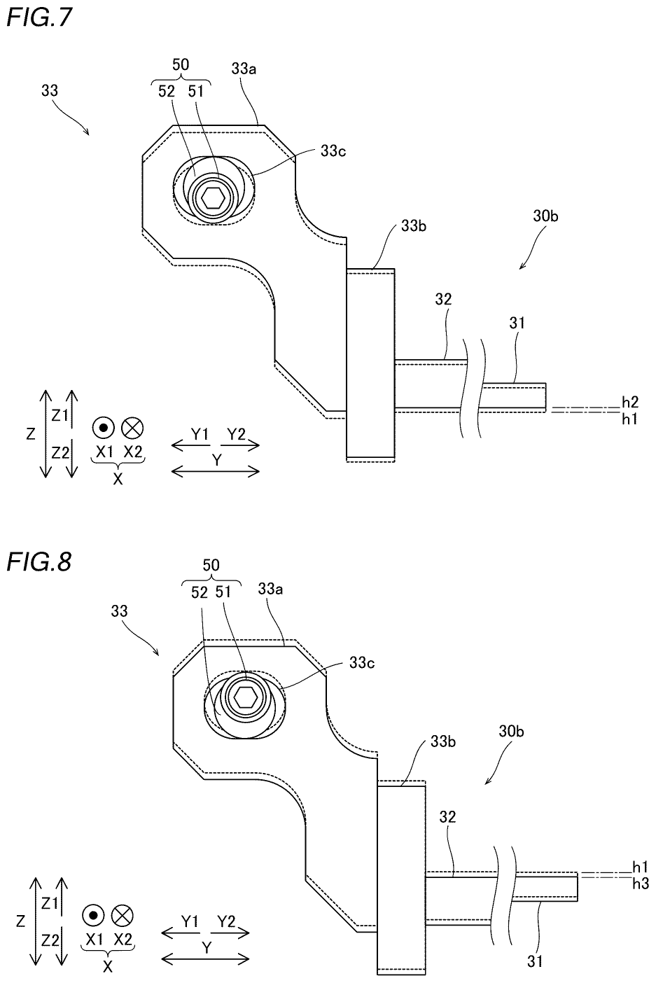

As shown in FIG. 5, the hole 33c of the second blade 30b has an ellipse shape. The height position of the second blade 30b is set h1 by rotating the eccentric bolt 50 so as to protrude the flange 52 in the Y1 direction. As shown in FIG. 7, the height position of the second blade 30b is set h2 higher than h1 by rotating the eccentric bolt 50 so as to protrude the flange 52 in the Z1 direction. As shown in FIG. 8, the height position of the second blade 30b is set h3 lower than h1 by rotating the eccentric bolt 50 so as to protrude the flange 52 in the Z2 direction. The height position of the second blade 30b is steplessly adjusted between h2 and h3 by rotating the eccentric bolt 50.

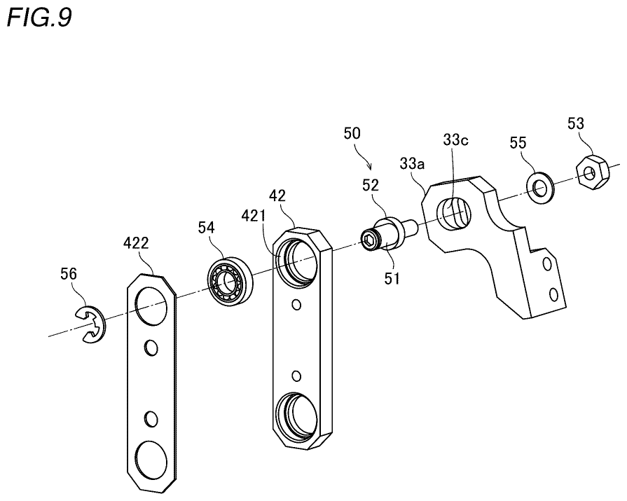

In the first embodiment, a nut 53 is threadedly engaged with one end part of the eccentric bolt 50 as shown in FIG. 9. The eccentric bolt 50 serves both as an element for fine adjustment of the height position of the second blade 30b in an upward/downward direction, and an element for fastening the second blade 30b to the second link 42. Specifically, a hole 421 is arranged in the second link 42. A ring-shaped bearing 54 is arranged in the hole 421. The second link 42 includes a cover 422 covering the bearing 54. The eccentric bolt 50 passes through the bearing 54, the hole 421 of the second link 42, and the hole 33c of the second blade 30b. The shaft 51 of the eccentric bolt 50 is supported by the bearing 54. The flange 52 of the eccentric bolt 50 is arranged in the hole 33c of the first connection part 33a of the second blade 30b. The second blade 30b is fastened to the second link 42 by threadedly engaging the nut 53 with the one end part of the eccentric bolt 50, which passes through the hole 33c of the first connection part 33a. A washer 55 is arranged on the one end part of the eccentric bolt 50. A snap ring 56 is fitted onto another end of the eccentric bolt 50.

### Advantages of First Embodiment

The plurality of second blades 30b are connected to the linkage 40 are connected by the eccentric bolts 50. Accordingly, because a height position of an upper end part of each eccentric bolt 50 is changed by changing a rotation angle of the eccentric bolt 50, it is possible to correspondingly change a height position of the second blade 30b relative to the linkage 40. Consequently, fine adjustment of the pitch p between the second blades 30b can be easily performed simply by changing the rotation angle of the eccentric bolt 50, which connects each of the plurality of second blade 30b to the linkage 40.

Each of the plurality of second blades 30b is connected to corresponding one of the plurality of second links 42 by corresponding one of the eccentric bolts 50. Accordingly, in the substrate-holding hand 20 including the linkage 40, which changes the pitch p between the second blades 30b, fine adjustment of the pitch p between the second blades 30b can be easily performed.

Fine adjustment of a height position of each of the plurality of second blades 30b is performed by moving the second blade 30b in an upward/downward direction by rotating the eccentric bolt 50 inserted in the hole 33c with the flange 52 being in contact with an interior side surface of the hole 33c. Accordingly, fine adjustment of the height position of the second blade 30b can be easily performed simply by rotating the eccentric bolt 50 about the rotation center axis C1.

The nut 53 is threadedly engaged with one end part of the eccentric bolt 50, and the eccentric bolt 50 serves both as an element for fine adjustment of the height position of the second blade 30b in an upward/downward direction, and an element for fastening the second blade 30b to the second link 42. Accordingly, it is possible to simplify the configuration the substrate-holding hand 20 as compared with a case in which an element for fine adjustment of the height position of the second blade 30b in an upward/downward direction, and an element for fastening the second blade 30b to the second link 42 are separately provided.

The third link 43 connecting the plurality of second links 42 to each other is provided. Accordingly, it is possible to transfer a driving force of the driver 60 from the first link 41 through the third link 43 to the plurality of second links 42.

The first blade 30a is fixed to the first substrate-holding hand 21, and the plurality of second blades 30b are provided forming the pitch p between the second blades 30b to be changed by the linkage 40. Accordingly, it is possible to easily perform fine adjustment of the pitch p between the second blades 30b, and to easily perform fine adjustment of the pitch p between the second blade 30b and the first blade 30a.

The connection part 33 of the second blade 30b is connected to the second link 42 by the eccentric bolt 50. Accordingly, because a height position of the connection part 33 is changed with respect to the second link 42 by changing a rotation angle of the eccentric bolt 50, it is possible to easily perform fine adjustment of the pitch p between the blade body 31 supported by the support 32 connected to the connection part 33.

### Second Embodiment

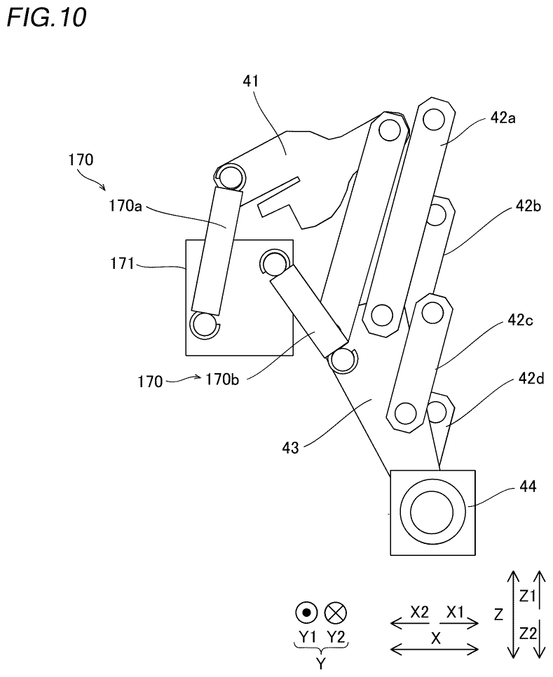

The following description describes a configuration of a biaser 170 according to a second embodiment. As shown in FIG. 10, the biaser 170 includes a pair of biasers 170a and 170b. The biaser 170a is connected to the first link 41 and a support 171. The biaser 170b is connected to the third link 43 and the support 171. The support 171 is an element fixed to the second substrate-holding hand 22. The biaser 170a and the biaser 170b are pulling coil springs that apply pulling forces to the first link 41 and the third link 43 to rotate the first link and the third link, respectively, in the direction that increases the pitch p between the blades 30. Because two biasers, which are the biaser 170a and the biaser 170b, are provided, it is possible to reduce extension amounts and spring forces required of the biaser 170a and the biaser 170b. The biasers 170, 170a and 170b are examples of a force applier.

### Modified Embodiments

Note that the embodiment disclosed this time must be considered as illustrative in all points and not restrictive. The scope of the present disclosure is not shown by the above description of the embodiments but by the scope of claims for patent, and all modifications (modified embodiments) within the meaning and scope equivalent to the scope of claims for patent are further included.

While the example in which four blades are provided as the second blades 30b has been shown in the aforementioned first and second embodiments, the present disclosure is not limited to this. The number of the second blade 30b can be anything number other than four.

While the example in which the linkage 40 includes the first link 41, the second link 42 and the third link 43 has been shown in the aforementioned first embodiment, the present invention is not limited to this. The number of types of links, and a shape of the linkage are not limited to the configuration of the linkage 40 according to the aforementioned first embodiment.

While the example in which the plurality of second blades 30b are supported by the linkage 40 for changing the pitch p between the second blades 30b has been shown in the aforementioned first and second embodiments, the present invention is not limited to this. For example, the second blades 30b may be supported by a support mechanism that supports the second blades with a fixed pitch p between the second blades 30b.

While the example in which fine adjustment of the height position of the second blade 30b is performed in an upward/downward direction by the eccentric bolt 50 has been shown in the aforementioned first and second embodiments, the present invention is not limited to this. Fine adjustment of the height position of the second blade 30b may be performed in the upward/downward direction by an eccentric element other than the eccentric bolt 50. For example, fine adjustment of the height position of the second blade 30b may be performed in the upward/downward direction by an eccentric rivet, an eccentric pin, an eccentric key, or the like.

While the example in which the eccentric bolt 50 serves both as an element for fine adjustment of the height position of the second blade 30b in an upward/downward direction, and an element for fastening the second blade 30b to the second link 42 has been shown in the aforementioned first and second embodiments, the present invention is not limited to this. An element for fine adjustment of the height position of the second blade 30b in an upward/downward direction, and an element for fastening the second blade 30b to the second link 42 may be separately provided. The second blade 30b may be fastened to the second link 42 by a bolt that is not eccentric with the height position of the second blade 30b being adjusted in the upward/downward direction by an eccentric element.

While the example in which all of the second links 42 are connected to their corresponding second blades 30b by their corresponding eccentric bolts 50 has been shown in the aforementioned first and second embodiments, the present invention is not limited to this. Some of the second links 42 may be connected to the second blades 30b by the eccentric bolts 50.

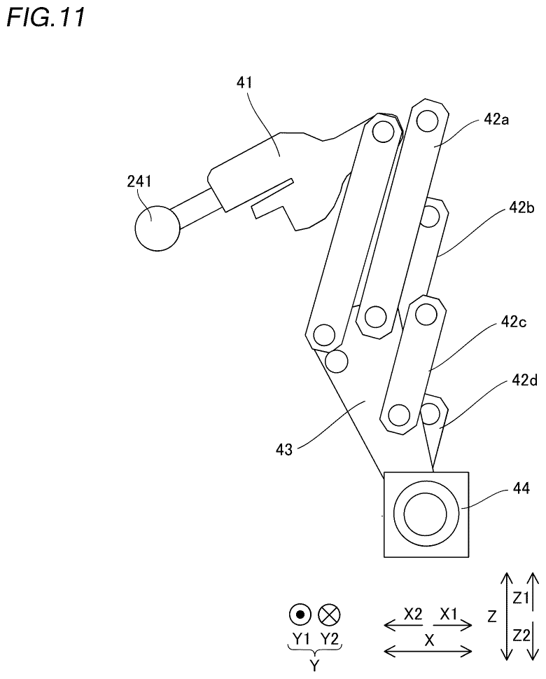

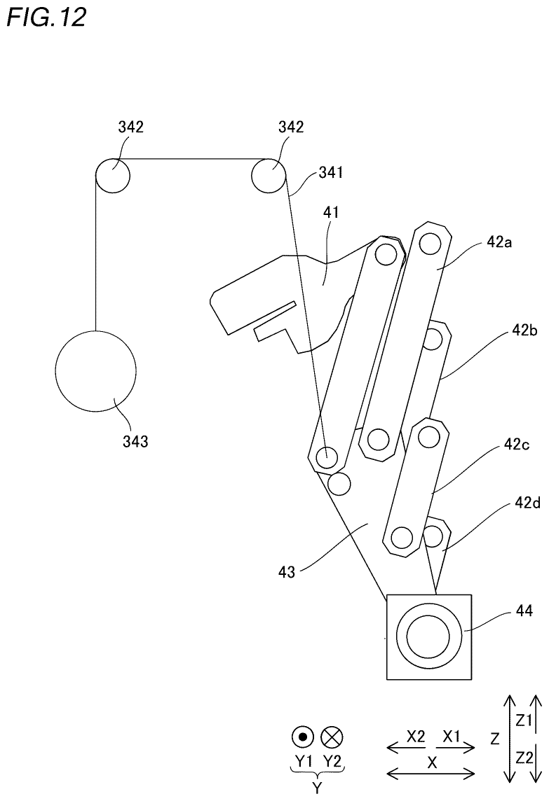

While the example in which the biasers 70 and 170, which are pulling coil springs, are used as a force applier that biases the linkage 40 in a direction that increases the pitch p between the blades 30 has been shown in the aforementioned first and second embodiments, the present invention is not limited to this. For example, as in a first modified embodiment shown in FIG. 11, a weight 241 may be provided to the first link 41 to rotate the first link 41 in a direction that increases the pitch p between the blades 30. Also, as in a second modified embodiment shown in FIG. 12, a weight 343 may be connected to the third link 43 through a wire 341 and pulleys 342 to rotate the third link 43 in a direction that increases the pitch p between the blades 30.

While the example in which the substrate-holding hand 20 includes the first substrate-holding hand 21 and the second substrate-holding hand 22 has been shown in the aforementioned first and second embodiments, the present invention is not limited to this. For example, the present disclosure can be applied to a substrate-holding hand that does not include the first substrate-holding hand 21.

### [Modes]

The aforementioned exemplary embodiment will be understood as concrete examples of the following modes by those skilled in the art.

### (Mode Item 1)

A substrate-holding hand includes a plurality of blades for supporting substrates and stacked with the plurality of blades being spaced away from each other; and a support mechanism for supporting the plurality of blades, wherein each of the plurality of blades is connected to the support mechanism by an eccentric element.

### (Mode Item 2)

In the substrate-holding hand according to mode item 1, the support mechanism includes a linkage for changing a pitch between the blades; the linkage includes a plurality of links; and each of the plurality of blades is connected to corresponding one of the plurality of links by the eccentric element.

### (Mode Item 3)

In the substrate-holding hand according to mode item 2, the blade includes a hole; the eccentric element includes an eccentric bolt including a shaft and a flange eccentrically arranged from a rotation center axis of the shaft, the eccentric bolt being inserted in the hole; and fine adjustment of a height position of each of the plurality of blades is performed by moving the blade in an upward/downward direction by rotating the eccentric bolt inserted in the hole with the flange being in contact with an interior side surface of the hole.

### (Mode Item 4)

In the substrate-holding hand according to mode item 3, the eccentric bolt includes an end part with which a nut is threadedly engaged; and the eccentric bolt serves both as an element for fine adjustment of the height position of each of the plurality of blades in an upward/downward direction, and an element for fastening the blade to corresponding one of the plurality of links.

### (Mode Item 5)

In the substrate-holding hand according to any of mode items 2 to 4, a driver for driving the linkage is further provided, wherein the plurality of links include a first link connected to the driver, and a plurality of second links connected to the plurality of blades; and each of the plurality of blades is connected to corresponding one of the plurality of second links by the eccentric element.

### (Mode Item 6)

In the substrate-holding hand according to mode item 5, the plurality of links further includes a third link connecting the plurality of second links to each other.

### (Mode Item 7)

In the substrate-holding hand according to any of mode items 2 to 6, a first substrate-holding hand, and a second substrate-holding hand arranged on or above the first substrate-holding hand for operating independently of the first substrate-holding hand, wherein the blades include a first blade provided to the first substrate-holding hand and fixed to the first substrate-holding hand, and a plurality of second blades provided to the second substrate-holding hand forming the pitch between the blades to be changed by the linkage.

### (Mode Item 8)

In the substrate-holding hand according to any of mode items 2 to 7, each of the plurality of blades includes a blade body for holding the substrate, a support supporting the blade body, and a connection part connecting the support to corresponding one of the plurality of links; and the connection part of each of the plurality of blades is connected to corresponding one of the plurality of links by the eccentric element.

### (Mode Item 9)

A substrate-conveying robot includes a robot arm, and a substrate-holding hand arranged in a distal end part of the robot arm, wherein the substrate-holding hand includes a plurality of blades for supporting substrates and stacked with the plurality of blades being spaced away from each other, and a support mechanism for supporting the plurality of blades, and each of the plurality of blades is connected to the support mechanism by an eccentric element.

1. A substrate-holding hand comprising:
a plurality of blades for supporting substrates and stacked with the plurality of blades being spaced away from each other; and
a support mechanism for supporting the plurality of blades, wherein
each of the plurality of blades is connected to the support mechanism by an eccentric element.

2. The substrate-holding hand according to claim 1, wherein
the support mechanism includes a linkage for changing a pitch between the blades;
the linkage includes a plurality of links; and
each of the plurality of blades is connected to corresponding one of the plurality of links by the eccentric element.

3. The substrate-holding hand according to claim 2, wherein
the blade includes a hole;
the eccentric element includes an eccentric bolt including a shaft and a flange eccentrically arranged from a rotation center axis of the shaft, the eccentric bolt being inserted in the hole; and
fine adjustment of a height position of each of the plurality of blades is performed by moving the blade in an upward/downward direction by rotating the eccentric bolt inserted in the hole with the flange being in contact with an interior side surface of the hole.

4. The substrate-holding hand according to claim 3, wherein
the eccentric bolt includes an end part with which a nut is threadedly engaged; and
the eccentric bolt serves both as an element for fine adjustment of the height position of each of the plurality of blades in an upward/downward direction, and an element for fastening the blade to corresponding one of the plurality of links.

5. The substrate-holding hand according to claim 2 further comprising
a driver for driving the linkage, wherein
the plurality of links include
a first link connected to the driver, and
a plurality of second links connected to the plurality of blades; and
each of the plurality of blades is connected to corresponding one of the plurality of second links by the eccentric element.

6. The substrate-holding hand according to claim 5, wherein the plurality of links further includes a third link connecting the plurality of second links to each other.

7. The substrate-holding hand according to claim 2 comprising a first substrate-holding hand, and a second substrate-holding hand arranged on or above the first substrate-holding hand for operating independently of the first substrate-holding hand, wherein
the blades include
a first blade provided to the first substrate-holding hand and fixed to the first substrate-holding hand, and
a plurality of second blades provided to the second substrate-holding hand forming the pitch between the blades to be changed by the linkage.

8. The substrate-holding hand according to claim 2, wherein
each of the plurality of blades includes
a blade body for holding the substrate,
a support supporting the blade body, and
a connection part connecting the support to corresponding one of the plurality of links; and
the connection part of each of the plurality of blades is connected to corresponding one of the plurality of links by the eccentric element.

9. A substrate-conveying robot comprising:
a robot arm; and
a substrate-holding hand arranged in a distal end part of the robot arm, wherein
the substrate-holding hand includes
a plurality of blades for supporting substrates and stacked with the plurality of blades being spaced away from each other, and
a support mechanism for supporting the plurality of blades, and
each of the plurality of blades is connected to the support mechanism by an eccentric element.
